(19) United States
(12) Patent Application Publication
(10) Pub. No.: US 2025/0300078 A1
(43) Pub. Date: Sep. 25, 2025

(54) HYBRID INTERCONNECT STRUCTURE WITH TOPOLOGICAL CONDUCTOR INTERFACE LAYER

(71) Applicant: INTERNATIONAL BUSINESS MACHINES CORPORATION, ARMONK, NY (US)

(72) Inventors: Ching-Tzu Chen, Ossining, NY (US); Takeshi Nogami, Schenectady, NY (US)

(21) Appl. No.: 18/614,794

(22) Filed: Mar. 25, 2024

(51) Int. Cl. H01L 23/528; H01L 21/768; H01L 23/532

(52) U.S. Cl. CPC H01L 23/5283; H01L 21/76831; H01L 21/76864; H01L 23/53209

(57) ABSTRACT

Embodiments of present invention provide a semiconductor structure. The semiconductor structure includes a non-topological conductor core, a topological conductor interface layer at least partially surrounding the non-topological conductor core, and a dielectric layer at least partially surrounding the topological conductor interface layer. Methods of forming the same is also provided.

### BACKGROUND

The present application relates to manufacturing of semiconductor integrated circuits. More particularly, it relates to a method of forming a hybrid interconnect structure with a topological conductor interface layer.

Extendibility of interconnects made from conductors such as Cu (copper) is problematic because charge carriers in conductive lines suffer surface and grain-boundary scattering at reduced dimensions, e.g., thicknesses and linewidths less than that of the electron free path, causing significant increase in resistivity. Furthermore, conventional copper interconnects require thick barrier/liner layers that take up additional conductor volume, further exacerbating the resistance increase and the resulting performance bottleneck.

Because of these constraints, alternative conductors with conventional conduction mechanisms and a slower increase in resistivity, such as Co, Ru, Ir, Rh, Mo, etc., are under active exploration as potential barrierless interconnects. However, these alternative, barrierless, non-topological conductors (Co, Ru, Ir, Rh etc.) still suffer from surface scattering and increased resistivity at reduced dimensions.

Also under exploration are unconventional, topological conductors, e.g., topological semimetals NbAs, CoSi, GaPd etc. These materials show decreasing resistance-area product (RA) and grain-boundary resistivity with scaling owing to a dominant surface-state conduction resilient against defect scattering. Despite a favorable RA scaling trend, however, topological semimetals generally contain lower carrier densities compared to conventional metals due to a smaller number of conducting states near the Fermi level, thus showing lower conductivity at, e.g., ≥3 nm.

### SUMMARY

Embodiments of present invention provide a semiconductor structure. The semiconductor structure includes a non-topological conductor core, a topological conductor interface layer at least partially surrounding the non-topological conductor core, and a dielectric layer at least partially surrounding the topological conductor interface layer.

According to one embodiment, the topological conductor interface layer covers a top portion of the non-topological conductor core.

In one embodiment, the topological conductor interface layer covers a bottom portion of the non-topological conductor core.

In another embodiment, the semiconductor structure further includes a liner layer at least partially surrounding the topological conductor interface layer.

According to yet another embodiment, a first portion of the liner layer and a second portion of the liner layer are intersected by sidewalls of the topological conductor interface layer.

In yet further embodiments, the first portion of the liner is formed underneath a bottom portion of the topological conductor interface layer.

According to another embodiment, bottom surfaces of the sidewalls of the topological conductor interface layer are coplanar with a bottom surface of the first portion of the liner layer.

In one embodiment, the topological conductor interface layer has a thickness ranging from 1-3 nm.

In another embodiment, a composition of the topological conductor interface layer is selected from a group consisting of topological semimetals, topological metals, chiral multifermion semimetals, type I Weyl semimetals, type II Weyl semimetals, magnetic Weyl semimetals, Heusler Weyl semimetals, Kramers Weyl semimetals, Dirac semimetals, and a combination thereof.

In some embodiments, the semiconductor structure further includes a charge carrier doping layer formed conformally between the topological conductor interface layer and the liner layer.

Embodiments of the present invention also provide a method of forming a semiconductor structure. The method includes forming a trench within a substrate, depositing a topological conductor interface layer conformally along the trench, thereby creating a remainder of the trench surrounded by the topological conductor interface layer, filling the remainder of the trench with a non-topological conductor core, and capping the substrate with a dielectric layer.

In one embodiment, the method further includes, prior to depositing the topological conductor interface layer, forming a liner layer conformally along the trench.

In another embodiment, the method further includes, after forming the liner layer, forming a charge carrier doping layer conformally along the liner layer.

In yet another embodiment, the method further includes, prior to capping the substrate with the dielectric layer, applying a planarization process to expose a top surface of the dielectric layer.

According to an embodiment, the topological conductor interface layer is formed by annealing two or more layers, and wherein at least one of the layers contains elements of a topological conductor.

Embodiments of the present invention also provide a method of forming a semiconductor structure. The method includes etching a non-topological conductor layer deposited on a substrate, thereby forming a non-topological conductor core, selectively forming a topological conductor interface layer on a top of and on sidewalls of the non-topological conductor core, and capping the topological conductor interface layer with a dielectric capping layer.

In an embodiment, the method further includes forming a liner layer in between the dielectric capping layer and the topological conductor interface layer.

In another embodiment, the method further includes, after forming the liner layer, forming a charge carrier doping layer conformally along the liner layer.

According to another embodiment, the method further includes forming the topological conductor interface layer in between the substrate and the non-topological conductor core; and forming the liner layer in between the substrate and the topological conductor interface layer.

In embodiments, the selectively forming the topological conductor interface layer on the sidewalls of the non-topological conductor core comprises forming the sidewalls of the topological conductor interface layer directly on top of the substrate.

### BRIEF DESCRIPTION OF THE DRAWINGS

The present invention will be understood and appreciated more fully from the following detailed description of embodiments of present invention, taken in conjunction with accompanying drawings.

FIG. 1 to FIG. 7 are demonstrative illustrations of cross-sectional views of a semiconductor structure 10 at various steps of manufacturing thereof according to embodiments of the present invention.

FIG. 8. is a demonstrative illustration of a flow-chart of a method of manufacturing the semiconductor structure 10 according to embodiments of the present invention.

FIG. 9 to FIG. 11 are demonstrative illustrations of cross-sectional views of a semiconductor structure 20 at various steps of manufacturing thereof according to embodiments of the present invention.

FIG. 12 is a demonstrative illustration of a flow-chart of a method of manufacturing the semiconductor structure 20 according to embodiments of the present invention.

FIG. 13 to FIG. 17 are demonstrative illustrations of cross-sectional views of a semiconductor structure 30 at various steps of manufacturing thereof according to embodiments of the present invention.

FIG. 18 is a demonstrative illustration of a flow-chart of a method of manufacturing the semiconductor structure 30 according to embodiments of the present invention.

FIG. 19 to FIG. 23 are demonstrative illustrations of cross-sectional views of a semiconductor structure 40 at various steps of manufacturing thereof according to embodiments of the present invention.

It will be appreciated that for simplicity and clarity purposes, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the case of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

In response to the problems detailed above with respect to extendibility of Cu interconnects and other interconnect technologies based on conventional, non-topological metals, the present invention was conceived to use non-topological metals as a core with a proximal surface layer of topological conductor to harness both the numerous bulk states in conventional conductors as well as the topologically protected surface states in topological conductors. The use of a low-resistivity conventional non-topological conductor wrapped in thin layer of topological conductor provides unique advantages and features that include a topological conductor interface layer that reduces interface scattering between interconnect wiring and dielectrics, a topological surface-state conduction that increases conductivity with decreasing layer thickness (providing parallel conduction), a bulk conventional conductor that maintains high bulk carrier density and bulk conductivity, and broad applicability for general purpose computing hardware. Using the structures and methods described herein, the present invention mitigates carrier scattering of conventional non-topological metal interconnects at the conductor-liner interface and the conductor-dielectric interface by leveraging the scattering resilient transport via the topological protected surface states in topological conductors. It also mitigates the challenges of low carrier densities in pristine topological semimetals by leveraging the numerous bulk carriers in conventional metals. The proposed interconnect structure thereby yields the desirable resistance scaling trend of decreasing line resistance with reduced feature size while retaining high conductivity.

FIG. 1 to FIG. 7 are demonstrative illustrations of cross-sectional views of the semiconductor structure 10 at various steps of manufacturing thereof according to embodiments of the present invention.

FIG. 1 is a demonstrative illustration of a cross-sectional view of a semiconductor structure in a step of manufacturing thereof according to one embodiment of the present invention.

Embodiments of the present invention provide forming a structure 10 by first receiving or providing a substrate 101, e.g., a dielectric substrate, with an opening such as a trench 102 formed into a top surface of the substrate 101. However, embodiments of present invention are not limited in this aspect and other types of substrates such as a semiconductor substrate with a top dielectric layer may be used as well.

In one embodiment, the substrate 101 is a low-k dielectric layer, for example, a blanket film of silicon oxide, SiCOH, SiCNO, SiCNH, SiCONH, etc., and the trench 102 is formed into the top surface of the substrate 101. The trench 102 may be formed by etching, e.g., wet/dry, and formed in a relatively rectangular cross-sectional shape. The trench 102 may have a high aspect ratio. Alternatively, the trench 102 may be formed in a V, circular, or any other cross-sectional shape.

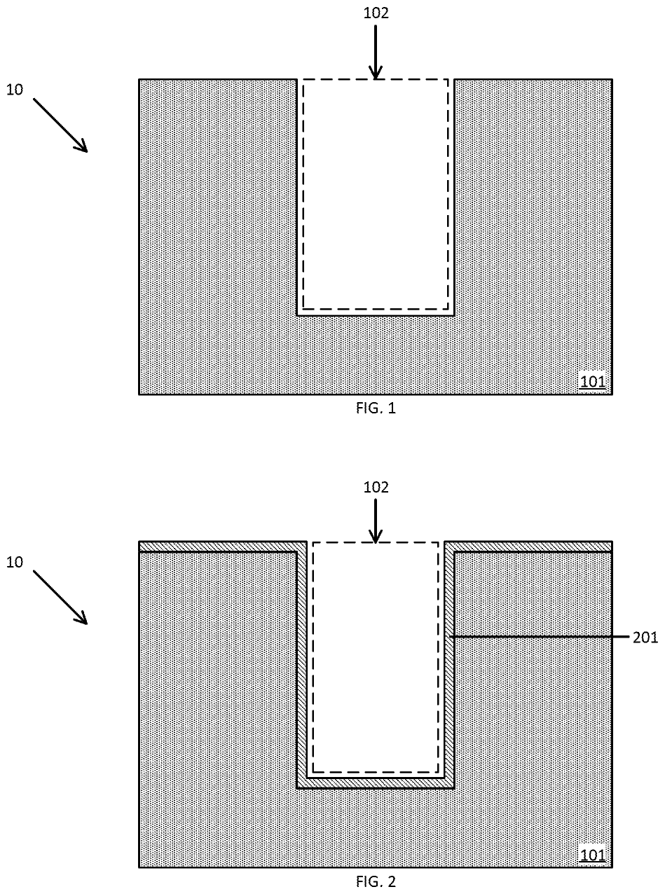

FIG. 2 is a demonstrative illustration of a cross-sectional view of a semiconductor structure in a step of manufacturing thereof according to one embodiment of the present invention.

Embodiments of the present invention further provide proceeding to form a liner layer 201 conformally within the trench 102 such that the liner layer 201 lines one or more sidewalls and a bottom surface of the trench 102. In embodiments, and as depicted in FIG. 2, the liner layer 201 may be also formed on top of the substrate 101, i.e., on a top surface of the substrate 101 where the trench 102 is not formed into.

In embodiments, the liner layer 201 may be a thin or proximal layer comprising 2D transition-metal dichalcogenides, graphene, silicene, other van der Waal materials, conventional metals (e.g., TaN, Ta, Nb, etc.), or combinations thereof. The liner layer 201 may be a layer of, for example, MoS2, WS2, TaS2, NbSe2, TiTe2, graphene, etc. The liner layer 201 may serve as an adhesion layer, a diffusion barrier, and/or a template for the growth of a subsequent layer, e.g., a topological conductor interface layer.

The liner layer 201 may be formed by deposition, for example thin-film deposition techniques such as atomic layer deposition (ALD).

In embodiments, the liner layer 201 and formation thereof may be omitted.

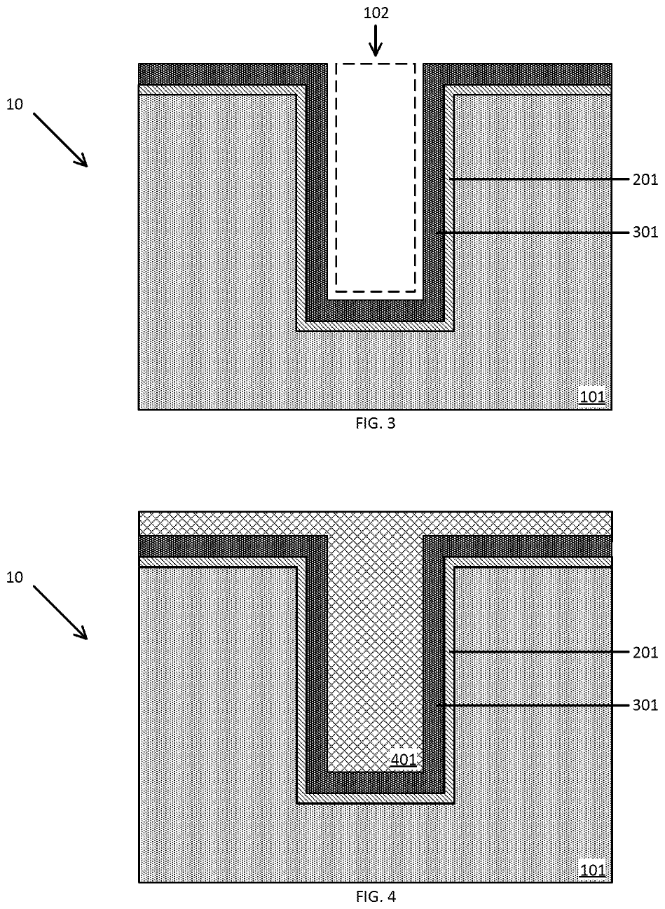

FIG. 3 is a demonstrative illustration of a cross-sectional view of a semiconductor structure in a step of manufacturing thereof according to one embodiment of the present invention.

Embodiments of the present invention further provide proceeding to form a topological conductor interface layer 301 conformally on top of the liner layer 201. In other words, the topological conductor interface layer 301 is formed conformally along the sidewalls of the liner layer 201 and on a top of the liner layer 201 that is within the bottom of the trench 102. In embodiments in which the liner layer 201 is additionally deposited on a top surface of the substrate 101 adjacent to the trench 102, e.g. an embodiment depicted by FIG. 3, the topological conductor interface layer 301 may be further formed in those areas on top of the liner layer 201.

A defining feature of a topological conductor is that regardless of its bulk, the surface has conducting surface states. The bulk can be insulating, conducting, or semi-metallic, etc., but nevertheless, the surface hosts conducting carriers. In embodiments, the topological conductor interface layer 301 may be a layer of topological semimetals, topological metals, or a combination thereof. In embodiments, for example, the topological conductor interface layer 301 is selected from chiral multifermion semimetals, (e.g. CoSi, RhSi, CoGe, RhGe, AlPt, AlPd, GaPt), Type I Weyl semimetals (e.g., TaAs, TaP, NbAs, Nb), Type II Weyl semimetals (e.g. (Mo,W)Te₂, (Mo,W)P₂, TaIrTe₄), Magnetic Weyl semimetals (e.g., (Co₃Sn₂S₂), Mn₃₊ₓSn₁₋ₓ, RAlGe where R is a rare earth metal), Heusler Weyl semimetals (GdPtBi, PdPtBi etc.), Kramers Weyl semimetals (Ag₃BO₃, Ag₂Se, etc.), Dirac semimetals (Na₃Bi, Cd₃As₂, EuCd₂As₂ etc.), topological metals (MoP, WC, etc.), and a combination thereof.

In one embodiment, the topological conductor interface layer 301 may be deposited by e-beam evaporation, sputter deposition, chemical vapor deposition, atomic layer deposition, etc. In embodiments, the topological conductor interface layer 301 is a uniform thickness. In embodiments, the topological conductor interface layer 301 is a thickness of 1-3 nm. In embodiments, the topological conductor interface layer having a thickness of 1-3 nm at least partially surrounding the non-topological conductor core 501 has been shown to mitigate/eliminate the problems detailed previously with respect to extendibility of conventional metal interconnects. Moreover, the use of the non-topological conductor core 501 wrapped in the topological conductor interface layer 301 further provides unique advantages and features that include a topological conductor interface layer that reduces interface scattering between interconnect wiring and dielectrics, a topological surface-state conduction that increases conductivity with decreasing layer thickness (providing parallel conduction), and a bulk conventional conductor that maintains high bulk carrier density and bulk conductivity, thereby yielding the desirable resistance scaling trend of decreasing line resistance with reduced feature size all while retaining high conductivity.

In one embodiment, the topological conductor interface layer 301 may be formed through an annealing process of one or more layers on the substrate 101. For example, adjacent layers of cobalt and silicon may be annealed to form CoSi or adjacent layers of rhodium and silicon may be annealed to form RhSi.

In embodiments in which the liner layer 201 is omitted, the non-topological conductor layer 301 may be formed on the substrate 101.

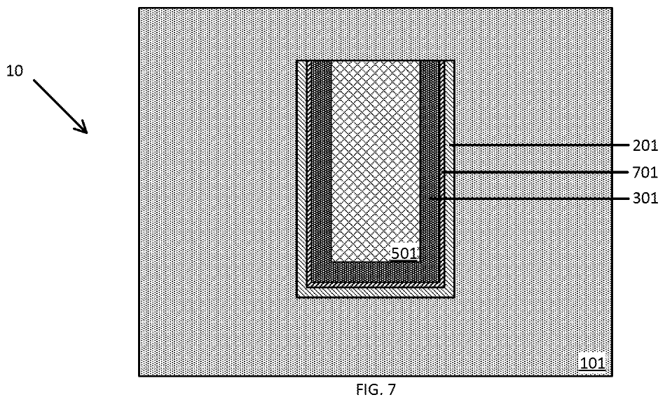

In embodiments, and as described in greater detail with respect to FIG. 7, a charge carrier doping layer may be formed on top of the liner layer 201 and/or the substrate 101.

FIG. 4. is a demonstrative illustration of a cross-sectional view of a semiconductor structure in a step of manufacturing thereof according to one embodiment of the present invention.

Embodiments of the present invention further provide proceeding to fill the trench 102 with a non-topological conductor layer 401. In embodiments, the non-topological conductor layer 401 may be further deposited on the liner layer 201 or the substrate 101 adjacent to the trench 102, e.g., as depicted by FIG. 4.

In one embodiment, the non-topological conductor layer 401 may be a layer of elemental metals, intermetallic metals, anisotropic conductors, MAX phase conductors, or a combination thereof, for example, Copper (Cu), Co, Ni, Ru, Ir, Rh, Mo, W, Nb, CuAl, CuAl2, CuAlx, PtCoO2, PdCoO2, CoSn, etc. In one embodiment, the non-topological conductor layer 401 may be formed by electroplating, sputtering, evaporation, CVD, ALD etc. As used herein, anisotropic conductors may conduct current differently based on direction whereas isotropic conductors induce electric current in a same direction when an electric field is applied.

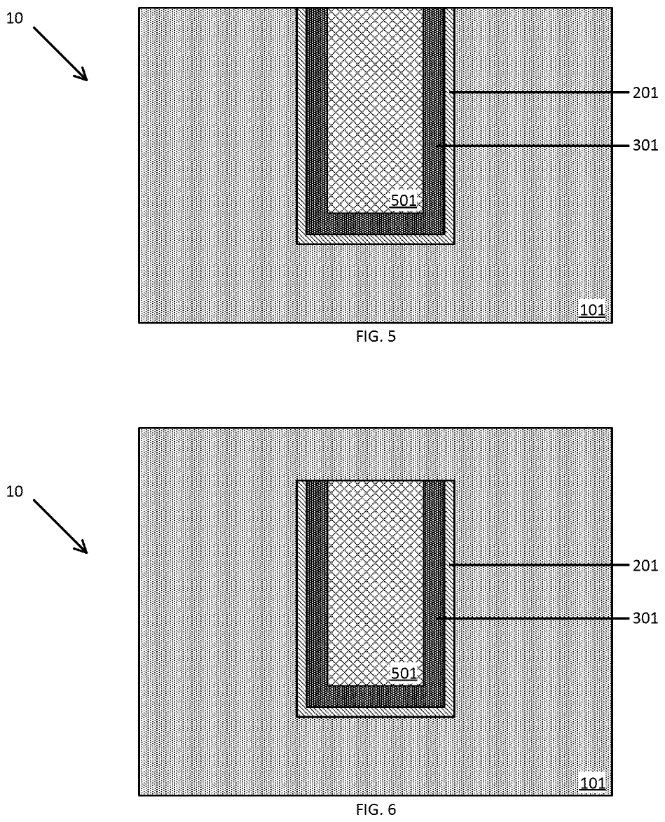

FIG. 5 is a demonstrative illustration of a cross-sectional view of a semiconductor structure in a step of manufacturing thereof according to one embodiment of the present invention.

Embodiments of the present invention further provide proceeding to perform a chemical-mechanical planarization (CMP) of the top of structure 10 down to and exposing the top of the substrate 101, removing portions of the liner layer 201, the topological conductor interface layer 301, and the non-topological conductor layer 401, forming a non-topological conductor core 501 within the trench 102. In embodiments, portions above a top surface of the substrate 101 are removed. The CMP process creates a coplanar surface of the non-topological conductor layer 401, the topological conductor interface layer 301, the liner layer 201, and the substrate 101. In doing so, the non-topological conductor core 501 is formed.

FIG. 6 is a demonstrative illustration of a cross-sectional view of a semiconductor structure in a step of manufacturing thereof according to one embodiment of the present invention.

Embodiments of the present invention further provide proceeding to cap the structure 10 with a dielectric layer which may be a same or different dielectric from the substrate 101, resulting in the encapsulation of the liner layer 201, the topological conductor interface layer 301, and the non-topological conductor core 501 within the substrate 101.

FIG. 7 is a demonstrative illustration of a cross-sectional view of a semiconductor structure in a step of manufacturing thereof according to one embodiment of the present invention.

Embodiments of the present invention optionally include forming a charge carrier doping layer 701 in contact with/between the liner layer 201 (when applicable) and the topological conductor interface layer 301. For example, the charge carrier doping layer 701 may be formed after formation of the liner layer 201 and prior to formation of the topological conductor interface layer 301. The charge carrier doping layer 701 may be metallic, such as disilicides (e.g., CoSi2), to interface with the topological conductor interface layer 301 (e.g., CoSi). Alternatively, the liner layer 201 (a diffusion barrier) of Ta or TaN may be leveraged to provide additional carriers for the topological conductor interface layer 301 (e.g., TaAs, TaP, etc.). The charge carrier doping layer 701 may be additionally and equally applicable to other disclosed embodiments of the present invention in which the liner layer 201 is utilized.

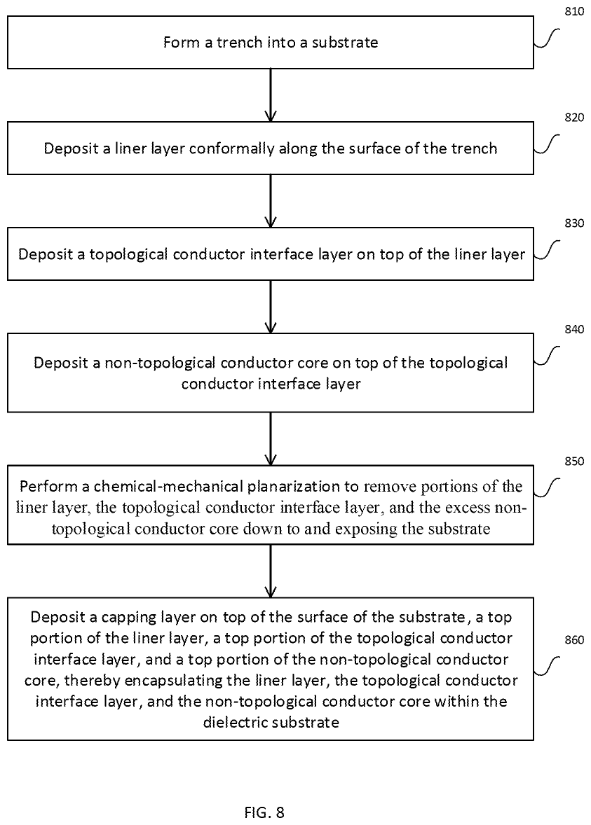

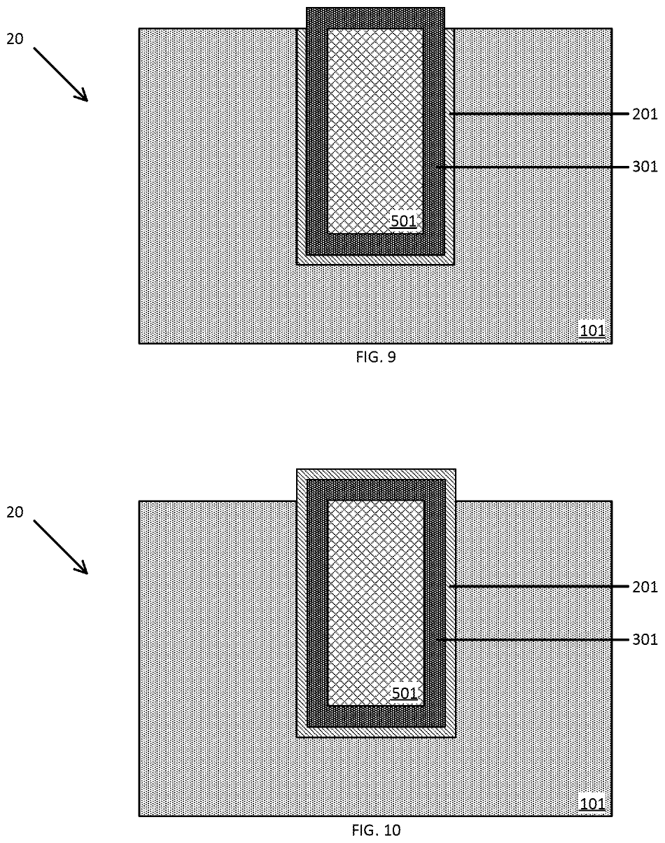

FIG. 8 is a demonstrative illustration of a flow-chart of a method of manufacturing the semiconductor structure 20 according to embodiments of the present invention. The method includes (810) forming a trench in a substrate; (820) depositing a liner layer conformally along the surface of the trench including sidewalls and a bottom of the trench; (830) depositing a topological conductor interface layer on top of the liner layer; (840) depositing a non-topological conductive core on top of the topological conductor interface layer; (850) performing a chemical-mechanical planarization to remove portions of the liner layer, the topological conductor interface layer, and the excess non-topological conductor core down to and exposing the substrate; and (860) depositing a capping layer on top of the substrate, a top surface of the liner layer, a top surface of the topological conductor interface layer, and a top surface of the non-topological conductor core, thereby encapsulating the liner layer, the topological conductor interface layer, and the non-topological conductor core within the substrate.

FIG. 9 to FIG. 11 are demonstrative illustrations of cross-sectional views of the semiconductor structure 20 at various steps of manufacturing thereof according to another embodiment of the present invention.

FIG. 9 is a demonstrative illustration of a cross-sectional view of a semiconductor structure in a step of manufacturing thereof according to one embodiment of the present invention.

Embodiments of the present invention further provide, after performing the CMP of the structure 10 as described with respect to FIG. 5, proceeding to form a portion of the topological conductor interface layer 301 on top of the non-topological conductor core 501. Here, the topological conductor interface layer 301 is formed using an area-selective deposition process to limit deposition exclusively to an area on top of the non-topological conductor core 501 as well as the topological conductor interface layer 301. In embodiments, and as a result, the topological conductor interface layer 301 wraps around the non-topological conductor core 501.

FIG. 10 is a demonstrative illustration of a cross-sectional view of a semiconductor structure in a step of manufacturing thereof according to one embodiment of the present invention.

Embodiments of the present invention further provide proceeding to form the liner layer 201 on top of the topological conductor interface layer 301. In embodiments, the liner layer 201 may be additionally deposited on exposed sides of the topological conductor interface layer 301. Here, the liner layer 201 is formed using area-selective deposition to limit deposition exclusively to an area on top of (and on the exposed sides of) the topological conductor interface layer 301. In embodiments, the liner layer 201 wraps around the topological conductor interface layer 301.

As an example, if the non-topological conductor core 501 is Co and the topological conductor interface layer 301 is CoSi, the process includes depositing Si at elevated temperatures, e.g., 550C or below, to form CoSi directly by solid-state epitaxy on top of the exposed Co, then removing the unreacted Si by etching, e.g., RIE, followed by area-selective deposition of the liner layer 201, e.g., transition metal dichalcogenide (TMD) liners.

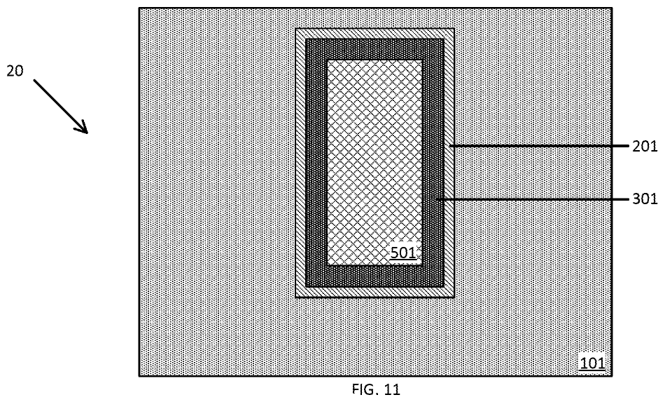

FIG. 11 is a demonstrative illustration of a cross-sectional view of a semiconductor structure in a step of manufacturing thereof according to one embodiment of the present invention.

Embodiments of the present invention further provide proceeding to cap the structure 20 with another dielectric layer which may be a same or different dielectric from the substrate 101, resulting in the encapsulation of the liner layer 201, the topological conductor interface layer 301, and the non-topological conductor core 501 within the substrate 101.

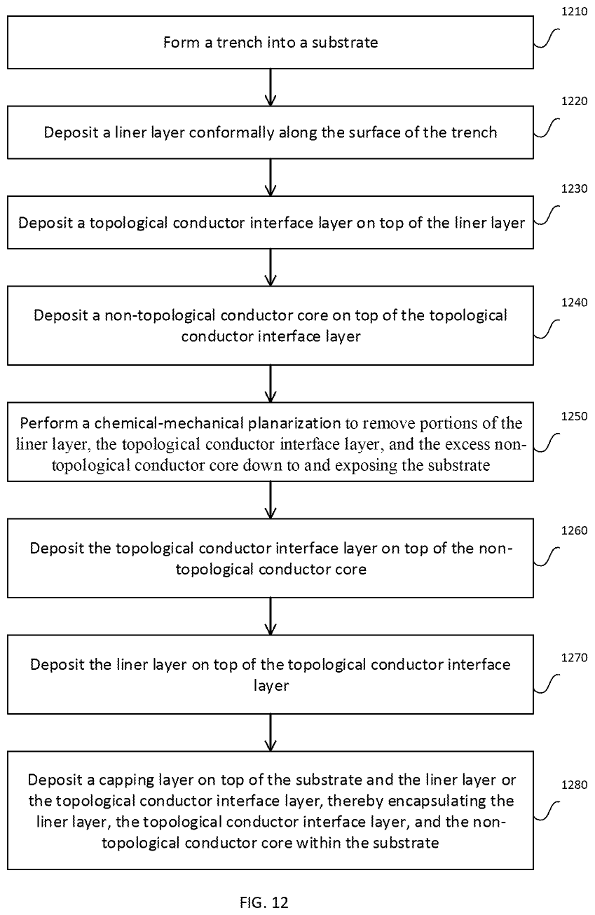

FIG. 12 is a demonstrative illustration of a flow-chart of a method of manufacturing the semiconductor structure 20 according to embodiments of the present invention. The method includes (1210) forming a trench in a substrate; (1220) depositing a liner layer conformally along the surface of the trench including sidewalls and a bottom of the trench; (1230) depositing a topological conductor interface layer on top of the liner layer; (1240) depositing a non-topological conductive core on top of the topological conductor interface layer; (1250) performing a chemical-mechanical planarization to remove portions of the liner layer, the topological conductor interface layer, and the excess non-topological conductor core down to and exposing the substrate; (1260) depositing the topological conductor interface layer on top of the non-topological conductor core; (1270) depositing the liner layer on top of the topological conductor interface layer; and (1280) depositing a capping layer on top of the substrate and the liner layer or the topological conductor interface layer, thereby encapsulating the liner layer, the topological conductor interface layer, and the non-topological conductor core within the substrate.

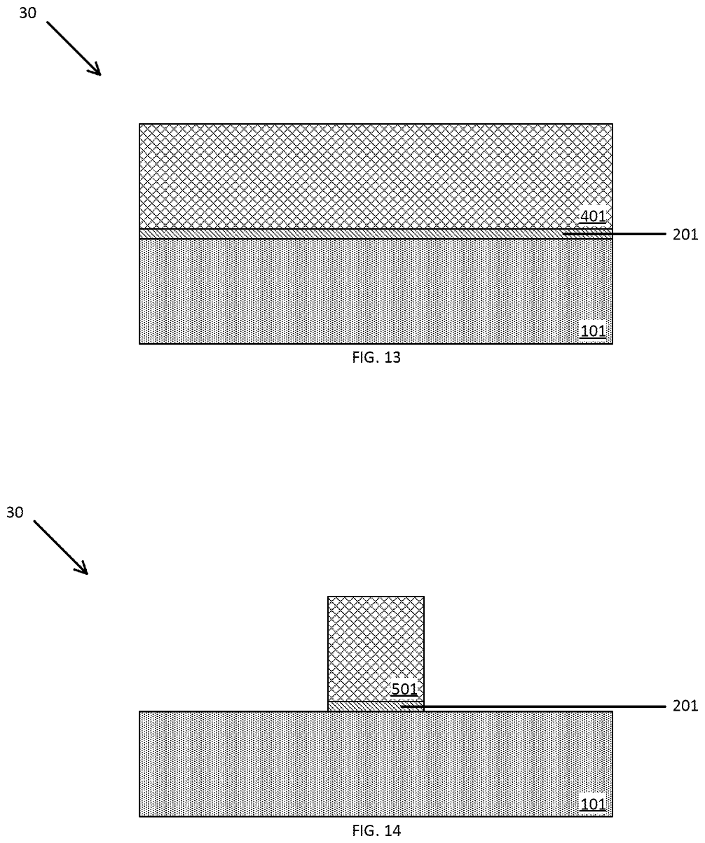

FIG. 13 to FIG. 17 are demonstrative illustrations of cross-sectional views of the semiconductor structure 30 at various steps of manufacturing thereof according to embodiments of the present invention.

FIG. 13 is a demonstrative illustration of a cross-sectional view of a semiconductor structure in a step of manufacturing thereof according to one embodiment of the present invention.

Embodiments of the present invention provide forming a structure 30 by first receiving or providing a substrate, for example the substrate 101, though the invention is not limited thereto. For example, the substrate may be a semiconductor substrate with a top dielectric layer. In embodiments, the substrate 101 is topped conformally by the liner layer 201 and the liner layer 201 is topped conformally by the non-topological conductor layer 401.

In embodiments, the liner layer 201 and formation thereof may be omitted. In such embodiments, the substrate 101 may be topped conformally by the non-topological conductor layer 401.

FIG. 14. is a demonstrative illustration of a cross-sectional view of a semiconductor structure in a step of manufacturing thereof according to one embodiment of the present invention.

Embodiments of the present invention further provide proceeding to use a subtractive patterning process to remove portions of the non-topological conductor layer 401 and the liner layer 201 (when applicable), leaving a non-topological conductor core 501 suitable for use as a conductive interconnect structure.

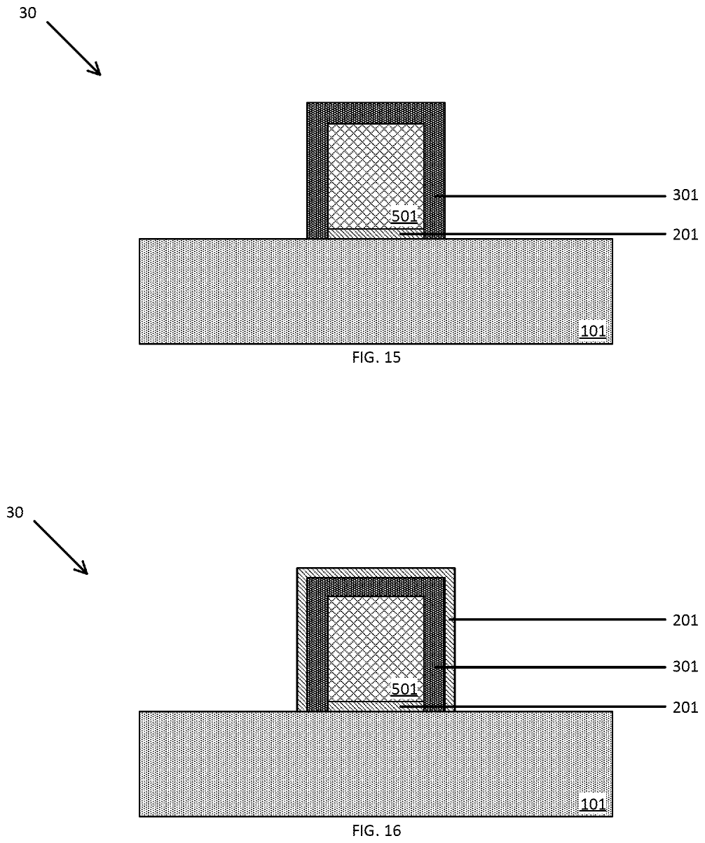

FIG. 15. is a demonstrative illustration of a cross-sectional view of a semiconductor structure in a step of manufacturing thereof according to one embodiment of the present invention.

Embodiments of the present invention further provide proceeding to deposit the topological conductor interface layer 301 conformally on a top and sides of the remaining portion of the non-topological conductor core 501. The deposition of the topological conductor interface layer 301 may be area-selective deposition. In embodiments, the topological conductor interface layer 301 may be additionally formed upon the exposed edges of the liner layer 201.

FIG. 16. is a demonstrative illustration of a cross-sectional view of a semiconductor structure in a step of manufacturing thereof according to one embodiment of the present invention.

Embodiments of the present invention further provide proceeding to deposit the liner layer 201 conformally on a top and sides of the topological conductor interface layer 301. The deposition of the liner layer 201 may be area-selective deposition.

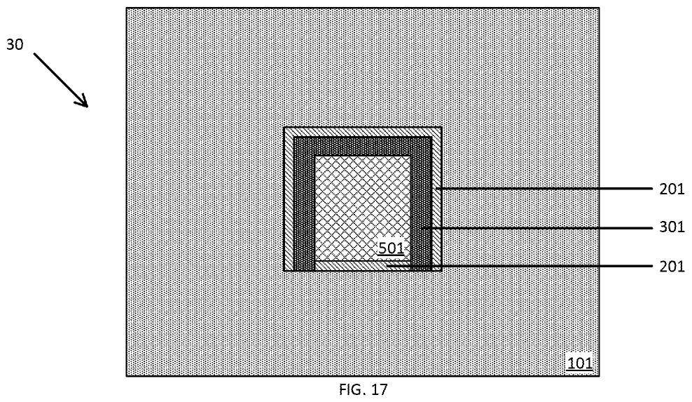

FIG. 17 is a demonstrative illustration of a cross-sectional view of a semiconductor structure in a step of manufacturing thereof according to one embodiment of the present invention.

Embodiments of the present invention further provide proceeding to cap the structure 30 with another dielectric layer which may be a same or different dielectric from the substrate 101, resulting in the encapsulation of the liner layer 201, the topological conductor interface layer 301, and the non-topological conductor core 501 within the substrate 101.

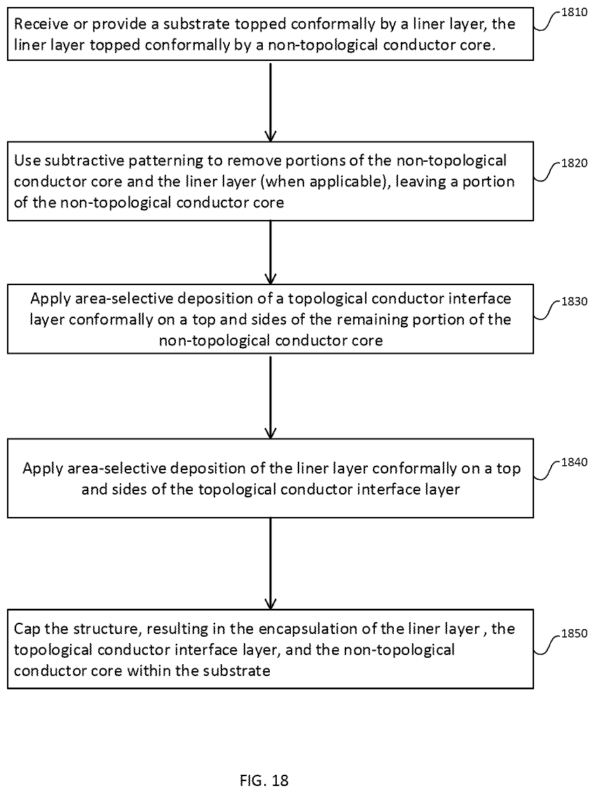

FIG. 18 is a demonstrative illustration of a flow-chart of a method of manufacturing the semiconductor structure 30 according to embodiments of the present invention. The method includes (1810) receiving or providing a substrate topped conformally by a liner layer, the liner layer topped conformally by a non-topological conductor core; (1820) using subtractive patterning to remove portions of the non-topological conductor core and the liner layer, leaving a portion of the non-topological conductor core; (1830) applying area-selective deposition of a topological conductor interface layer conformally on a top and sides of the remaining portion of the non-topological conductor core; (1840) applying area-selective deposition of the liner layer conformally on a top and sides of the topological conductor interface layer; and (1850) capping the structure, resulting in the encapsulation of the liner layer, the topological conductor interface layer, and the non-topological conductor core within the substrate.

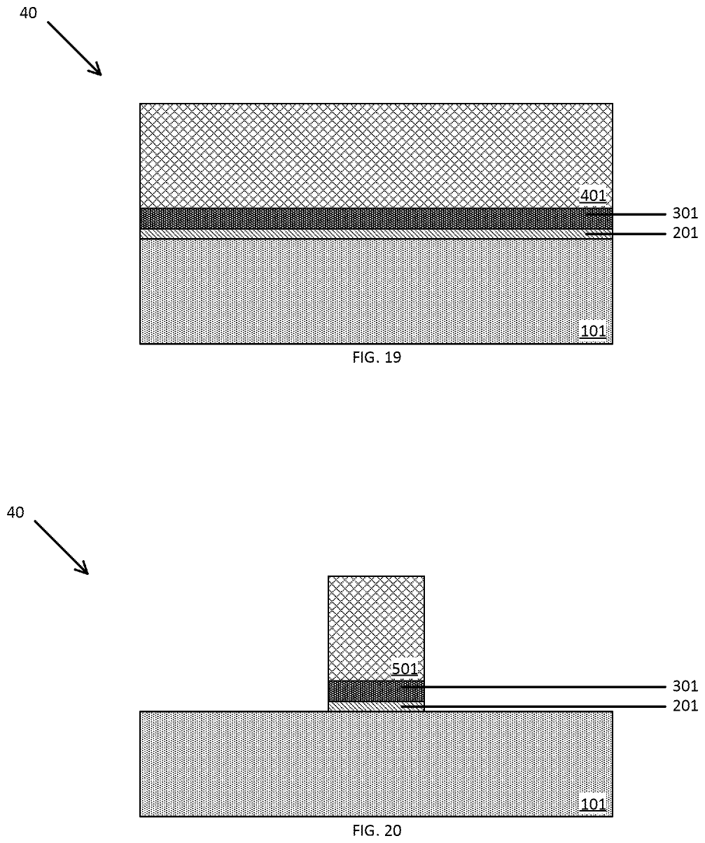

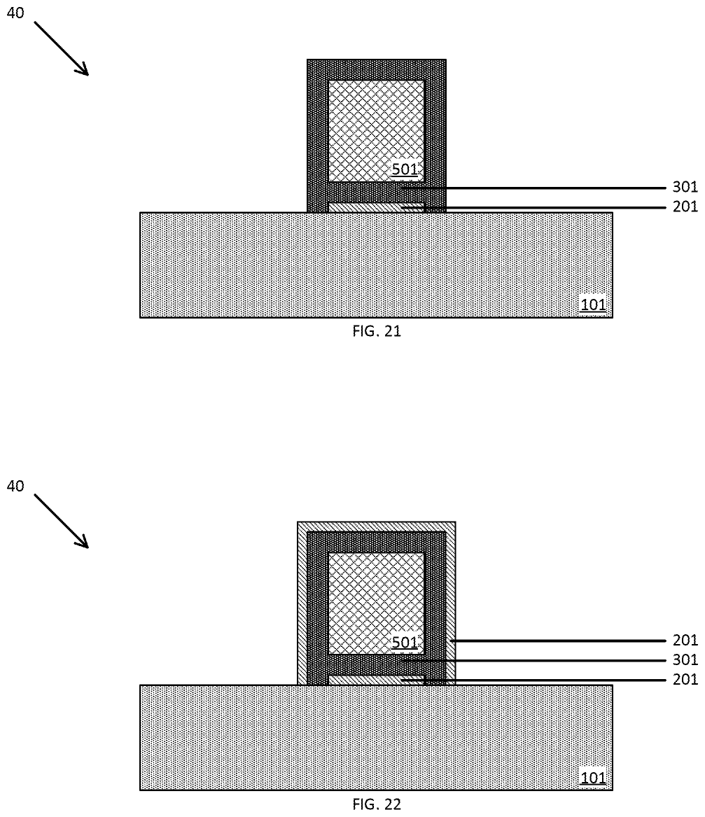

FIG. 19 to FIG. 23 are demonstrative illustrations of cross-sectional views of the semiconductor structure 40 at various steps of manufacturing thereof according to embodiments of the present invention.

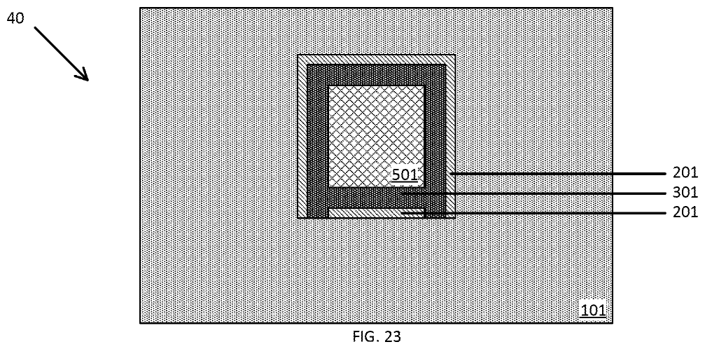

FIG. 19 to FIG. 23 depict an embodiment of the present invention similar to that depicted by and described with respect to FIG. 13 to FIG. 17. Here, however, the topological conductor interface layer 301 is additionally formed in between the liner layer 201 and the non-topological conductor layer 401 (see FIG. 19). Such an embodiment allows for the non-topological conductor core 501 to be wrapped around entirely by the topological conductor interface layer 301 (see FIG. 23).

Various examples may possibly be described by one or more of the following features in the following numbered clauses:

Clause 1: A semiconductor structure, the semiconductor structure comprising a non-topological conductor core; a topological conductor interface layer at least partially surrounding the non-topological conductor core; and a dielectric layer at least partially surrounding the topological conductor interface layer.

Clause 2: The semiconductor structure of claim 1, wherein the topological conductor interface layer covers a top portion of the non-topological conductor core.

Clause 3: The semiconductor structure of claim 2, wherein the topological conductor interface layer covers a bottom portion of the non-topological conductor core.

Clause 4: The semiconductor structure of claim 1, further comprising a liner layer at least partially surrounding the topological conductor interface layer.

Clause 5: The semiconductor structure of claim 4, wherein a first portion of the liner layer and a second portion of the liner layer are intersected by sidewalls of the topological conductor interface layer.

Clause 6: The semiconductor structure of claim 5, wherein the first portion of the liner is formed underneath a bottom portion of the topological conductor interface layer.

Clause 7: The semiconductor structure of claim 5, wherein bottom surfaces of the sidewalls of the topological conductor interface layer are coplanar with a bottom surface of the first portion of the liner layer.

Clause 8: The semiconductor structure of claim 1, wherein the topological conductor interface layer has a thickness ranging from 1-3 nm.

Clause 9: The semiconductor structure of claim 1, wherein a composition of the topological conductor interface layer is selected from a group consisting of topological semimetals, topological metals, chiral multifermion semimetals, type I Weyl semimetals, type II Weyl semimetals, magnetic Weyl semimetals, Heusler Weyl semimetals, Kramers Weyl semimetals, Dirac semimetals, and a combination thereof.

Clause 10: The semiconductor structure of claim 4, further comprising a charge carrier doping layer formed conformally between the topological conductor interface layer and the liner layer.

Clause 11: A method of forming a semiconductor structure, the method comprising forming a trench within a substrate; depositing a topological conductor interface layer conformally along the trench, thereby creating a remainder of the trench surrounded by the topological conductor interface layer; filling the remainder of the trench with a non-topological conductor core; and capping the substrate with a dielectric layer.

Clause 12: The method of claim 11, further comprising prior to depositing the topological conductor interface layer, forming a liner layer conformally along the trench.

Clause 13: The method of claim 12, further comprising after forming the liner layer, forming a charge carrier doping layer conformally along the liner layer.

Clause 14: The method of claim 11, further comprising prior to capping the substrate with the dielectric layer, applying a planarization process to expose a top surface of the dielectric layer.

Clause 15: The method of claim 11, wherein the topological conductor interface layer is formed by annealing two or more layers, and wherein at least one of the layers contains elements of a topological conductor.

Clause 16: A method of forming a semiconductor structure, the method comprising etching a non-topological conductor layer deposited on a substrate, thereby forming a non-topological conductor core; selectively forming a topological conductor interface layer on a top of and on sidewalls of the non-topological conductor core; and capping the topological conductor interface layer with a dielectric capping layer.

Clause 17: The method of claim 16, further comprising forming a liner layer in between the dielectric capping layer and the topological conductor interface layer.

Clause 18: The method of claim 17, further comprising after forming the liner layer, forming a charge carrier doping layer conformally along the liner layer.

Clause 19: The method of claim 1, further comprising forming the topological conductor interface layer in between the substrate and the non-topological conductor core; and forming the liner layer in between the substrate and the topological conductor interface layer.

Clause 20: The method of claim 16, wherein the selectively forming the topological conductor interface layer on the sidewalls of the non-topological conductor core comprises forming the sidewalls of the topological conductor interface layer directly on top of the substrate.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure, the semiconductor structure comprising:
a non-topological conductor core;
a topological conductor interface layer at least partially surrounding the non-topological conductor core; and
a dielectric layer at least partially surrounding the topological conductor interface layer.

2. The semiconductor structure of claim 1, wherein the topological conductor interface layer covers a top portion of the non-topological conductor core.

3. The semiconductor structure of claim 2, wherein the topological conductor interface layer covers a bottom portion of the non-topological conductor core.

4. The semiconductor structure of claim 1, further comprising:
a liner layer at least partially surrounding the topological conductor interface layer.

5. The semiconductor structure of claim 4, wherein a first portion of the liner layer and a second portion of the liner layer are intersected by sidewalls of the topological conductor interface layer.

6. The semiconductor structure of claim 5, wherein the first portion of the liner is formed underneath a bottom portion of the topological conductor interface layer.

7. The semiconductor structure of claim 5, wherein bottom surfaces of the sidewalls of the topological conductor interface layer are coplanar with a bottom surface of the first portion of the liner layer.

8. The semiconductor structure of claim 1, wherein the topological conductor interface layer has a thickness ranging from 1-3 nm.

9. The semiconductor structure of claim 1, wherein a composition of the topological conductor interface layer is selected from a group consisting of topological semimetals, topological metals, chiral multifermion semimetals, type I Weyl semimetals, type II Weyl semimetals, magnetic Weyl semimetals, Heusler Weyl semimetals, Kramers Weyl semimetals, Dirac semimetals, and a combination thereof.

10. The semiconductor structure of claim 4, further comprising:
a charge carrier doping layer formed conformally between the topological conductor interface layer and the liner layer.

11. A method of forming a semiconductor structure, the method comprising:
forming a trench within a substrate;
depositing a topological conductor interface layer conformally along the trench, thereby creating a remainder of the trench surrounded by the topological conductor interface layer;
filling the remainder of the trench with a non-topological conductor core; and
capping the substrate with a dielectric layer.

12. The method of claim 11, further comprising:
prior to depositing the topological conductor interface layer, forming a liner layer conformally along the trench.

13. The method of claim 12, further comprising:
after forming the liner layer, forming a charge carrier doping layer conformally along the liner layer.

14. The method of claim 11, further comprising:
prior to capping the substrate with the dielectric layer, applying a planarization process to expose a top surface of the dielectric layer.

15. The method of claim 11, wherein the topological conductor interface layer is formed by annealing two or more layers, and wherein at least one of the layers contains elements of a topological conductor.

16. A method of forming a semiconductor structure, the method comprising:
etching a non-topological conductor layer deposited on a substrate, thereby forming a non-topological conductor core;
selectively forming a topological conductor interface layer on a top of and on sidewalls of the non-topological conductor core; and
capping the topological conductor interface layer with a dielectric capping layer.

17. The method of claim 16, further comprising:
forming a liner layer in between the dielectric capping layer and the topological conductor interface layer.

18. The method of claim 17, further comprising:
after forming the liner layer, forming a charge carrier doping layer conformally along the liner layer.

19. The method of claim 1, further comprising:
forming the topological conductor interface layer in between the substrate and the non-topological conductor core; and
forming the liner layer in between the substrate and the topological conductor interface layer.

20. The method of claim 16, wherein the selectively forming the topological conductor interface layer on the sidewalls of the non-topological conductor core comprises forming the sidewalls of the topological conductor interface layer directly on top of the substrate.
